(19) United States
(12) Patent Application Publication
(10) Pub. No.: US 2024/0363347 A1
(43) Pub. Date: Oct. 31, 2024

(54) METHOD FOR METAL PATTERNING

(71) Applicant: TAIWAN SEMICONDUCTOR MANUFACTURING COMPANY, LTD., Hsinchu (TW)

(72) Inventors: Chia-Chen LEE, Hsinchu (TW); Chia-Tien WU, Hsinchu (TW)

(73) Assignee: TAIWAN SEMICONDUCTOR MANUFACTURING COMPANY, LTD., Hsinchu (TW)

(21) Appl. No.: 18/308,117

(22) Filed: Apr. 27, 2023

(51) Int. Cl. H01L 21/033; H01L 21/308; H01L 21/311

(52) U.S. Cl. CPC H01L 21/0337; H01L 21/3086; H01L 21/31144

(57) ABSTRACT

A method for metal patterning is provided. A plurality of mandrel recesses are formed in a mandrel layer over a semiconductor substrate. A plurality of spacers are formed respectively in the mandrel recesses. Each of the spacers is connected to a sidewall of the corresponding one of the mandrel recesses and has a spacer recess formed therein. A plurality of filling features are formed respectively in the spacer recesses. A first patterning process is performed to pattern the mandrel layer to form a first line pattern. A second patterning process is performed to pattern the filling features to form a second line pattern. A plurality of metal lines are formed in the semiconductor substrate, and are arranged in a pattern that is a combination of the first line pattern and the second line pattern.

### BACKGROUND

With the development of semiconductor technology, sizes of circuit elements and spacings between circuit elements (i.e., the pitches) are reduced to improve power and speed performance of integrated circuits (ICs). Lithography techniques play an important role in size and pitch reductions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram that illustrates metal lines that are formed using a method for metal patterning in accordance with some embodiments.

FIG. 2 is a flow chart that illustrates steps of the method for metal patterning in accordance with some embodiments.

FIGS. 3A, 3B, 4A, 4B, 5A, 5B, 6A, 6B, 7A, 7B, 8A, 8B, 8C, 9A, 9B, 9C, 10A, 10B, 10C, 11A, 11B, 11C, 12A, 12B, 12C, 13A, 13B, 14A and 14B are top views and sectional views of intermediate stages of the method for metal patterning in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly.” “upwardly,” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

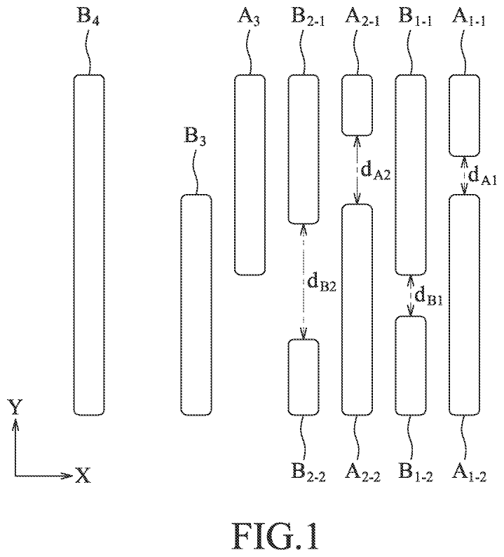

FIG. 1 illustrates an example of metal lines formed on a semiconductor substrate (not shown) using a self-aligned double patterning technique in accordance with some embodiments of this disclosure. The metal lines extend in a Y-axis direction and are classified into a first metal line group that includes metal lines A₁₋₁, A₁₋₂, A₂₋₁, A₂₋₂ and A₃, and a second metal line group that includes metal lines B₁₋₁, B₁₋₂, B₂₋₁, B₂₋₂, B₃ and B₄. In the illustrative embodiment, a distance between adjacent metal lines in each of the first metal line group and the second metal line group is large enough for a lithography (also called photolithography) exposure tool to complete the patterning for the first metal line group or the second metal line group in a single exposure process with good reliability. In some embodiments, a distance between a metal line belonging to the first metal line group (e.g., the metal line A₁₋₁) and an adjacent metal line belonging to the second metal line group (e.g., the metal line B₁₋₁) may be so small and beyond an exposure limit of the lithography exposure tool that the patterning for the first metal line group and the second metal line group cannot be completed in a single exposure process with an acceptable reliability. Accordingly, the self-aligned double patterning technique may be needed to form the illustrative pattern, and the patterning for the first metal line group and the patterning for the second metal line group are separately performed (i.e., two separate exposure processes). In the illustrative embodiment, a single metal line may have a line width in a range from about 5 nm to about 1000 μm, a spacing distance between two metal lines (e.g., the metal line A₁₋₁ and the metal line B₁₋₁) that are adjacent in an X-axis direction (i.e., a direction perpendicular to the Y-axis direction) may range from about 5 nm to about 50 nm, and a line-end distance between two metal lines (e.g., the metal line A₁₋₁ and the metal line A₁₋₂) that are adjacent and aligned in the Y-axis direction may range from about 2 nm to about 50 nm. Although the metal lines are depicted to have the same line width in FIG. 1, this disclosure is not limited in this respect. In other embodiments, the line widths of the metal lines may vary. In the illustrative embodiment, looking only at the first metal line group, the metal lines A₁₋₁ and A₁₋₂ are adjacent to the metal lines A₂₋₁ and A₂₋₂ in the X-axis direction, and a spacing between the metal lines A₁₋₁ and A₁₋₂ overlaps a spacing between the metal lines A₂₋₁ and A₂₋₂ when viewed in the X-axis direction, where the spacing between the metal lines A₁₋₁ and A₁₋₂ is different from the spacing between the metal lines A₂₋₁ and A₂₋₂ in length (i.e., the line-end distance d_{A1} is different from the line-end distance d_{A2}). Similarly, looking only at the second metal line group, the metal lines B₁₋₁ and B₁₋₂ are adjacent to the metal lines B₂₋₁ and B₂₋₂ in the X-axis direction, and a spacing between the metal lines B₁₋₁ and B₁₋₂ overlaps a spacing between the metal lines B₂₋₁ and B₂₋₂ when viewed in the X-axis direction, where the spacing between the metal lines B₁₋₁ and B₁₋₂ is different from the spacing between the metal lines B₂₋₁ and B₂₋₂ in length (i.e., the line-end distance d_{B1} is different from the line-end distance d_{B2}).

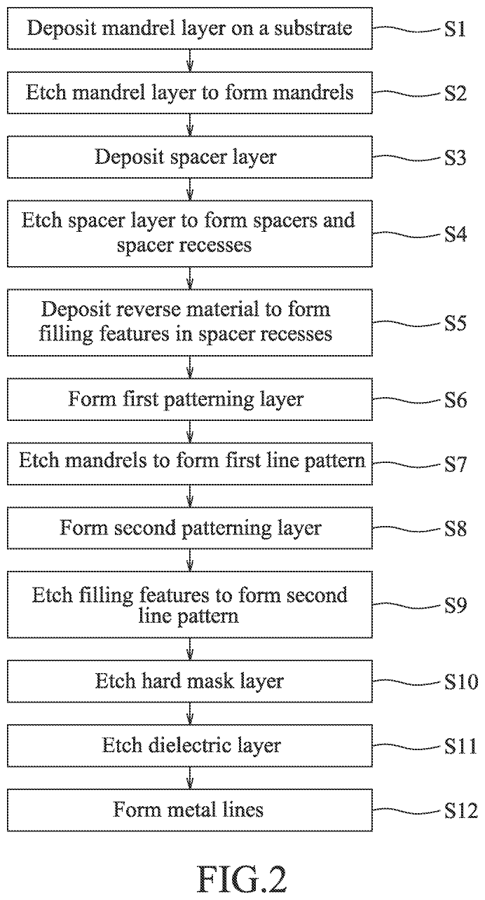

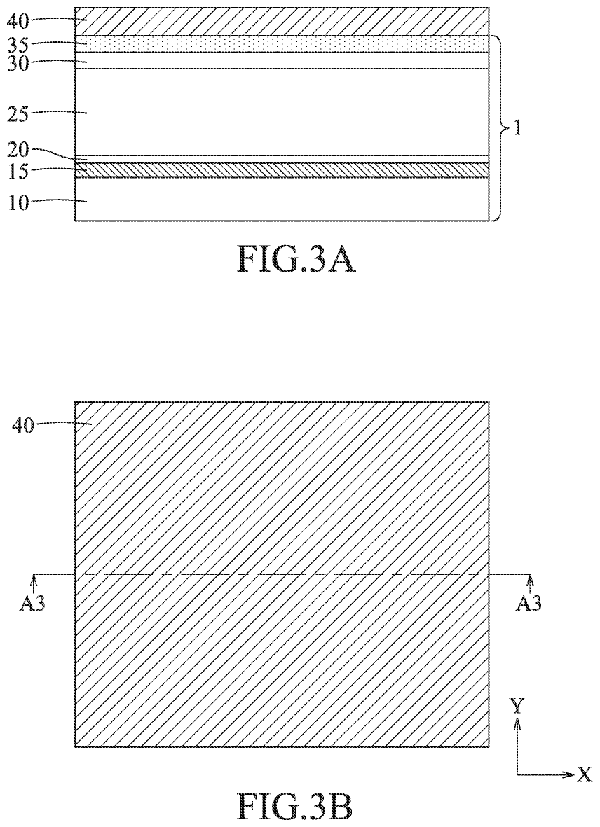

FIG. 2 is a flow chart that cooperates with FIGS. 3A, 3B, 4A, 4B, 5A, 5B, 6A, 6B, 7A, 7B, 8A, 8B, 8C, 9A, 9B, 9C, 10A, 10B, 10C, 11A, 11B, 11C, 12A, 12B, 12C, 13A, 13B, 14A and 14B to exemplarily describe fabrication of the metal lines as exemplified in FIG. 1 using a method for metal patterning in accordance with some embodiments of this disclosure.

Referring to FIGS. 2, 3A and 3B, a mandrel layer 40 is formed over a semiconductor substrate 1 (step S1), where FIG. 3B is a top view of a structure at this stage, and FIG. 3A depicts a sectional view taken along line A3-A3 in FIG. 3B. In the illustrative embodiment, the semiconductor substrate 1 includes a semiconductor device layer 10, a conductor layer 15 formed over the semiconductor device layer 10, an etch stop layer 20 formed over the conductor layer 15, a dielectric layer 25 formed over the etch stop layer 20, a first thin film layer 30 formed over the dielectric layer 25, and a second thin film layer 35 formed over the first thin film layer 30, wherein the first thin film layer 30 and the second thin film layer 35 cooperatively form a masking layer that is used to pattern the dielectric layer 25.

The semiconductor device layer 10 may include a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The semiconductor device layer 10 may be made of a suitable semiconductor material, such as silicon or the like. In some embodiments, the semiconductor device layer 10 is a silicon substrate; and in other embodiments, the semiconductor device layer 10 is made of a compound semiconductor such as silicon carbide, gallium arsenide, indium arsenide, indium phosphide or other suitable materials. In still other embodiments, the semiconductor device layer 10 is made of an alloy semiconductor such as GaAsP, AlInAs, AlGaAs, GaInAs, GaInP, GaInAsP or other suitable materials.

In some embodiments, the semiconductor device layer 10 includes various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the semiconductor device layer 10 may include other functional elements such as resistors, capacitors, diodes, transistors, and/or the like. The transistors are, for example, field effect transistors (FETs), such as planar FETs and/or 3D FETs (e.g., FinFETs, GAAFETs). The semiconductor device layer 10 may include lateral isolation features (e.g., shallow trench isolation (STI)) configured to separate various functional elements formed on the semiconductor device layer 10 and/or various functional elements formed in the semiconductor device layer 10.

The conductor layer 15 may be formed with conductor lines, and may include, for example, Cu, Ru, W, Ti, Al, Co, Mo, Ir, Rh, C, NiₓAl_{y}, CuₓAl_{y}, ScₓAl_{y}, RuₓAl_{y}, other suitable materials, or any combination thereof. In accordance with some embodiments, the conductor layer 15 may have a thickness in a range from about 100 angstroms to about 2000 angstroms.

The etch stop layer 20 may be of a single layer structure or a multi-layer structure depending on etch stop requirements, and may include, for example, SiCN, SiO₂, SiNₓ, AlOₓN_{y}, metal oxide (represented as MOₓ, where M can be, for example, Ru, W, Ta, Ti, Al, Co, or other suitable metal elements), other suitable materials, or any combination thereof. Each layer of the etch stop layer 20 may have a thickness in a range from about 5 angstroms to about 200 angstroms in accordance with some embodiments.

The dielectric layer 25 may include, for example, silicon containing oxide/nitride (e.g., Siₓ₁Oₓ₂, Siₓ₁Nₓ₂, Siₓ₁Oₓ₂Cₓ₃, Siₓ₁Oₓ₂Cₓ₃Nₓ₄, or other suitable compositions), metal oxide/nitride/carbide (e.g., AlOₓ, AlOₓN_{y}, AlOₓC_{y}, or other suitable compositions), other suitable materials, or any combination thereof, and may be formed using, for example, an oxygen-doped carbide (ODC) process, a nitrogen-doped carbide (NDC) process, a tetraeythlorthosilicate (TEOS) oxide process, a plasma enhanced oxide (PEOX) process, other suitable processes, or any combination thereof. In accordance with some embodiments, the dielectric layer 25 may have a thickness in a range from about 100 angstroms to about 5000 angstroms.

Each of the first thin film layer 30 and the second thin film layer 35 may include, for example, SiCN, SiO₂, SiNₓ, AlOₓN_{y}, metal oxide (MOₓ, where M can be, for example, Ru, W, Ta, Ti, Al, Co, or other suitable metal elements), other suitable materials, or any combination thereof. The first thin film layer 30 and the second thin film layer 35 each may be formed into a single-layer structure or a multi-layer structure depending on its function, such as serving as an etching stop or a patterning mask. In the illustrative embodiment, the first thin film layer 30 may be used as an etch stop layer during etching of the second thin film layer 35, and the second thin film layer 35 may be used as a hard mask layer for patterning the dielectric layer 25. In accordance with some embodiments, each of the first thin film layer 30 and the second thin film layer 35 may have a thickness in a range from about 30 angstroms to about 500 angstroms.

The mandrel layer 40 may be of a single-layer structure or a multi-layer structure, and may include, for example, SiCN, SiO₂, SiNₓ, AlOₓN_{y}, metal oxide (MOₓ, where M can be, for example, Ru, W, Ta, Ti, Al, Co, or other suitable metal elements), other suitable materials, or any combination thereof. The mandrel layer 40 may be formed using, for example, physical vapor deposition (PVD), chemical vapor deposition (CVD), atomic layer deposition (ALD), other suitable techniques, or any combination thereof, and has a thickness in a range from about 30 angstroms to about 500 angstroms in accordance with some embodiments.

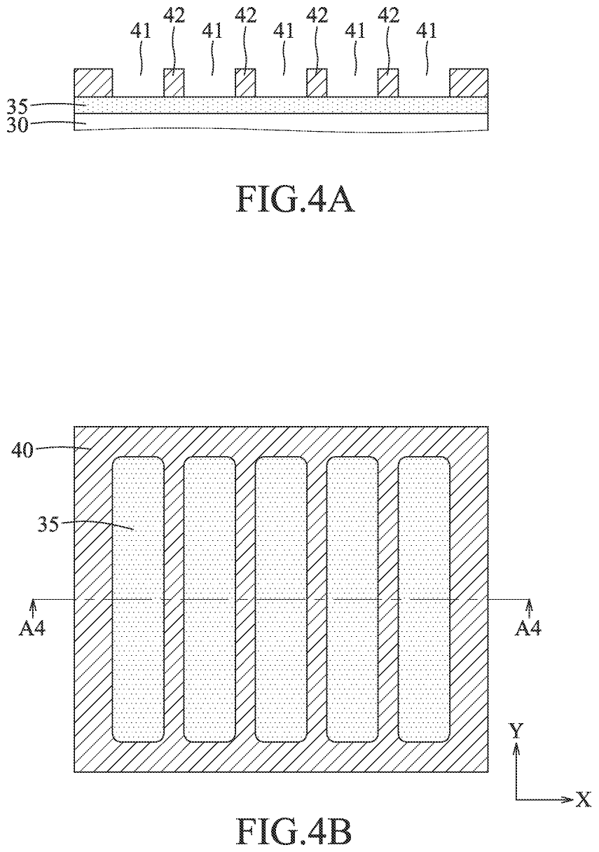

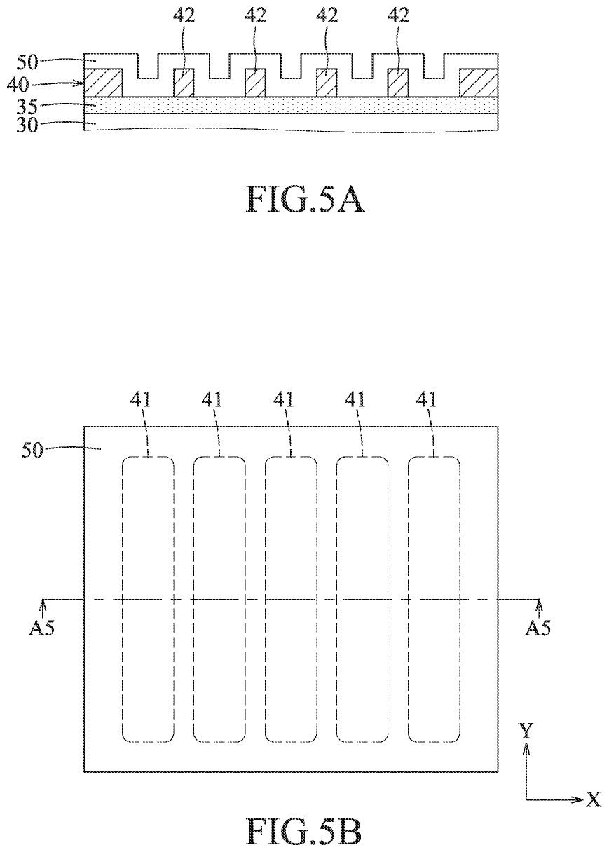

Referring to FIGS. 2, 4A and 4B, the mandrel layer 40 is patterned (step S2) through, for example, a lithography process, an etching process and/or a trimming process, to form in the mandrel layer 40 a plurality of mandrel recesses (or called openings) 41 that expose the second thin film layer 35. The etching process may include, for example, wet etching, dry etching, other suitable techniques, or any combination thereof. FIG. 4B is a top view of a structure at this stage, and FIG. 4A depicts a sectional view taken along line A4-A4 in FIG. 4B. It is noted that FIG. 4A omits the layers 10, 15, 20 and 25 for the sake of clarity, and so do FIGS. 5A, 6A, 7A, 8A, 8B, 9A, 9B, 10A, 10B, 11A, 11B, 12A and 12B. The mandrel recesses 41 are arranged in the X-axis direction, extend in the Y-axis direction, and form a plurality of mandrels 42 in the mandrel layer 40, where the mandrels 42 are arranged in the X-axis direction and extend in the Y-axis direction. Each of the mandrels 42 is a portion of the mandrel layer 40 that is disposed between adjacent two of the mandrel recesses 41. The widths of the mandrel recesses 41 (i.e., the width of the mandrel openings) are related to the widths of the metal lines of the second metal line group in FIG. 1, and the widths of the mandrels 42 are related to the widths of the metal lines of the first metal line group in FIG. 1. Although the mandrel recesses 41 appear to have the same widths and the mandrels 42 appear to have the same widths in the illustrative embodiment, this disclosure is not limited in this respect. In other embodiments, the widths of the mandrel recesses 41 may be different from each other, and the widths of the mandrels 42 may be different from each other as well.

Referring to FIGS. 2, 5A and 5B, a spacer layer 50 is conformally deposited over the mandrel layer 40 and in the mandrel recesses 41 (step S3) using, for example, PVD. CVD, ALD, other suitable techniques, or any combination thereof. The spacer layer 50 may include, for example, silicon containing oxide/nitride (e.g., Siₓ₁Oₓ₂, Siₓ₁Nₓ₂, Siₓ₁Oₓ₂Cₓ₃, Siₓ₁Oₓ₂Cₓ₃Nₓ₄, or other suitable compositions), metal oxide/nitride/carbide (e.g., MOₓ, MOₓN_{y}, MOₓC_{y}, where M can be, for example, Ru, W, Ta, Ti, Al, Co, or other suitable metal elements), other suitable materials, or any combination thereof, and may be formed using, for example, an ODC process, an NDC process, a TEOS oxide process, a PEOX process, other suitable processes, or any combination thereof. In accordance with some embodiments, the material used in the spacer layer 50 is different from the material used in the mandrel layer 40, so that the spacer layer 50 would not be removed during the subsequent etching of the mandrels 42. A thickness of the spacer layer 50 is related to the line widths of the metal lines of the second metal line group and the spacing distances between a metal line of the first metal line group and an adjacent metal line of the second metal line group, and thus may be determined based on requirements. In accordance with some embodiments, the thickness of the spacer layer 50 may range from about 5 nm to about 50 nm.

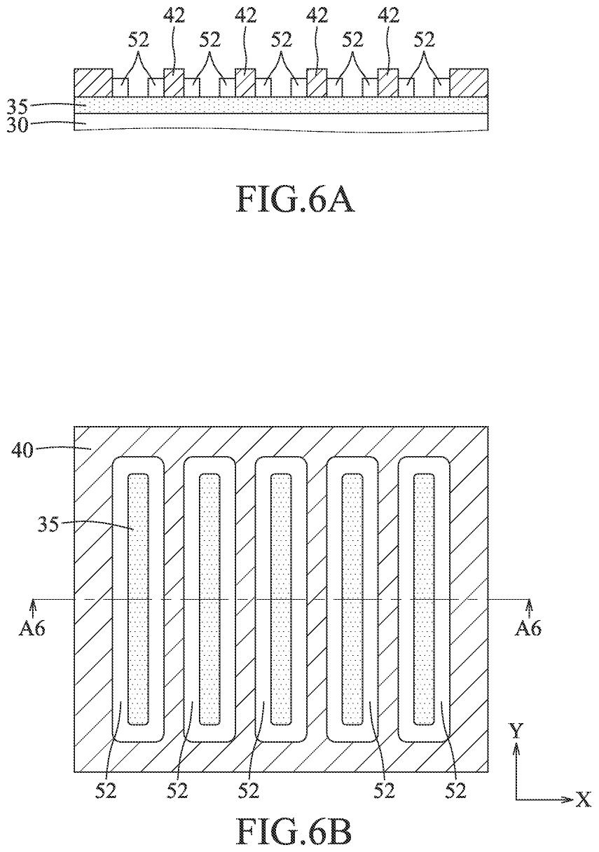

Referring to FIGS. 2, 6A and 6B, the spacer layer 50 is etched anisotropically (step S4) using, for example, wet etching, dry etching, other suitable techniques, or any combination thereof, to reveal a top surface of the mandrel layer 40 and to form spacer recesses (or called openings) in the spacer layer 50 and respectively in the mandrel recesses 41 by removing portions of the spacer layer 50 that are over the mandrels 42 and portions of the spacer layer 50 that are disposed at the bottom of the mandrel recesses 41 (sec FIGS. 5A and 5B). The spacer recesses extend in the Y-axis direction and expose the second thin film layer 35 of the masking layer. Because the etching of the spacer layer 50 is anisotropic, portions of the spacer layer 50 that are formed on sidewalls of the mandrel recesses 41 (namely, the sidewalls of the mandrels 42) are maintained. The maintained portions of the spacer layer 50 form a plurality of spacers 52 respectively in the mandrel recesses 41. Each of the spacers 52 is connected to the sidewall of the corresponding one of the mandrel recesses 41 and has the spacer recess formed therein. In the illustrative embodiment, each of the spacer recesses is formed to have a respective uniform width in the X-axis direction in order to form a corresponding metal line that has a uniform width, but this disclosure is not limited in this respect.

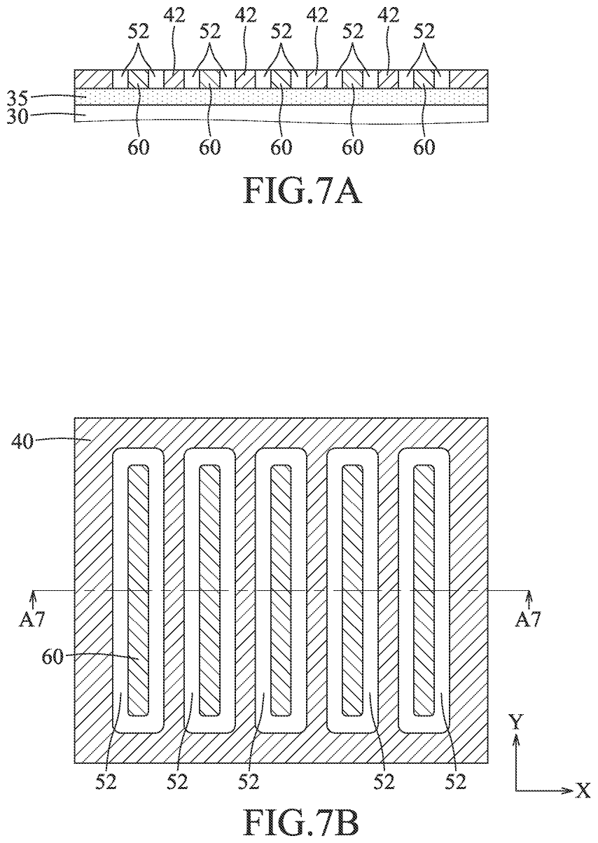

Referring to FIGS. 2, 7A and 7B, a plurality of filling features 60 are formed respectively in the spacer recesses (step S5). FIG. 7B is a top view of a structure at this stage, and FIG. 7A depicts a sectional view taken along line A7-A7 in FIG. 7B. The filling features 60 that fill the spacer recesses are made of a reverse material that includes, for example, silicon containing oxide/nitride (e.g., Siₓ₁Oₓ₂, Siₓ₁Nₓ₂, Siₓ₁Oₓ₂Cₓ₃, Siₓ₁Oₓ₂Cₓ₃Nₓ₄, or other suitable compositions), metal oxide/nitride/carbide (e.g., MOₓ, MOₓN_{y}, MOₓC_{y}, where M can be, for example, Ru, W, Ta, Ti, Al, Co, or other suitable metal elements), other suitable materials, or any combination thereof, and may be formed using, for example, an oxygen-doped carbide (ODC) process, a nitrogen-doped carbide (NDC) process, a tetraeythlorthosilicate (TEOS) oxide process, a plasma enhanced oxide (PEOX) process, other suitable processes, or any combination thereof. In accordance with some embodiments, the material used in the filling features 60 is different from the material used in the spacer layer 50, so that the spacer layer 50 would not be removed during the subsequent etching of the filling features 60. In accordance with some embodiments, in order to form the filling features 60 in the spacer recesses, a reverse material layer is deposited on the mandrel layer 40 and the spacers 52 and in the spacer recesses, and then a planarization process is performed on the reverse material layer to reveal the mandrel layer 40 and the spacers 52, so as to form the filling features 60 that are formed by portions of the reverse material layer filled in the spacer recesses, and to make the mandrels 42, the spacers 52 and the filling features 60 have the same height or thickness in a range of, for example, from about 10 angstroms to about 500 angstroms. In accordance with some embodiments, the planarization process may include, for example, dry etching, chemical-mechanical planarization (CMP), other suitable techniques, or any combination thereof. The filling features 60 are formed to fit the widths of the spacer recesses defined by the spacers 52, and thus each of the filling features 60 extends in the Y-axis direction and has a respective uniform width the same as the corresponding spacer recess 51 in the illustrative embodiment. The filling features 60 are used to be formed with a pattern of the metal lines of the second metal line group (see FIG. 1) in later process steps, so the metal lines of the second metal line group would have the desired line widths as defined by the spacers 52 (e.g., the widths of the filling features 60).

Following step S5, a first patterning process is performed to pattern the mandrel layer 40 to form a first line pattern. In accordance with some embodiments, the first patterning process may include steps S6 and S7 as illustrated in FIG. 2.

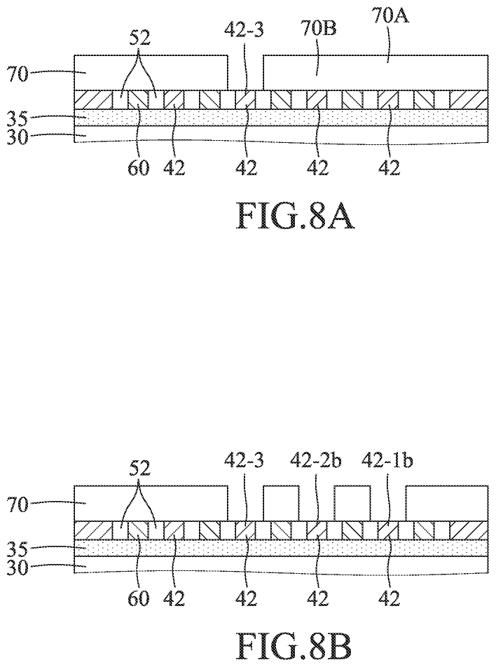

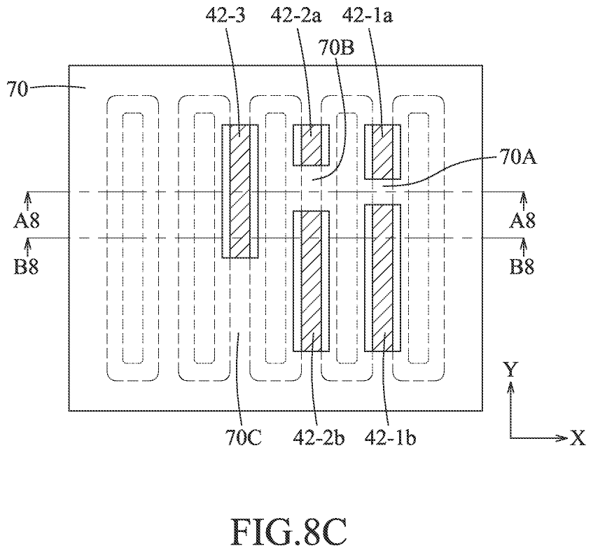

Referring to FIGS. 2, 8A, 8B and 8C, a first patterning layer 70 is formed over the mandrel layer 40, the spacers 52 and the filling features 60 (step S6). FIG. 8C is a top view of a structure at this stage, FIG. 8A depicts a sectional view taken along line A8-A8 in FIG. 8C, and FIG. 8B depicts a sectional view taken along line B8-B8 in FIG. 8C. The first patterning layer 70 covers each of the filling features 60 (namely, the filling features 60 are masked by the first patterning layer 70) and is formed with multiple openings that correspond to the first line pattern and that expose parts of the mandrels 42 of the mandrel layer 40 through a lithography process. In the illustrative embodiment, the first patterning layer 70 includes first to fifth openings that respectively expose five portions 42-1a, 42-1b, 42-2a, 42-2b and 43 of the mandrels 42 of the mandrel layer 40, which respectively correspond in position to the metal lines A₁₋₁, A₁₋₂, A₂₋₁, A₂₋₂ and A₃ of the first metal line group in FIG. 1. A portion 70A of the first patterning layer 70 covers and crosses a middle part of one of the mandrels 42 (referred to as a first mandrel 42 hereinafter), and separates the first opening and the second opening from each other in the Y-axis direction by a distance ranging from about 2 nm to about 50 nm, so as to define the line-end distance d_{A1} in FIG. 1. A portion 70B of the first patterning layer 70 covers and crosses a middle part of another mandrel 42 (referred to as a second mandrel 42 hereinafter) that is adjacent to the first mandrel 42 (i.e., there is no other mandrels 42 between the first and second mandrels 42), and separates the third opening and the fourth opening from each other in the Y-axis direction by a distance ranging from about 2 nm to about 50 nm, so as to define the line-end distance d_{A2} in FIG. 1. When the line-end distance (i.e., a distance between adjacent ends of two lines that extend in the same direction and that are aligned with and adjacent to each other in the extending direction) is smaller than 2 nm, the two lines may be too close to achieve a reliable exposure. It is noted that although the embodiment is applicable to a case where the line-end distance is greater than 50 nm (e.g., 10 μm is also an applicable line-end distance), the process introduced herein may be more suitable than some conventional processes when the line-end distance is smaller than 50 nm because 50 nm may be too small for those conventional processes to achieve a reliable exposure. A portion 70C of the first patterning layer 70 covers a lower part (lower from the perspective of FIG. 8C) of yet another mandrel 42 whereas portion of the first patterning layer 70 that correspond in position to lower parts of the first and second mandrels 42 are formed with the second and fourth openings, respectively. In the illustrative embodiment, the portions 70A and 70B that respectively correspond to the adjacent first and second mandrels 42 overlap each other when viewed in the X-axis direction, and have different lengths in the Y-axis direction. In the illustrative embodiment, since the openings of the first patterning layer 70 are formed in positions corresponding to where the metal lines of the first metal line group are to be formed instead of where no metal line of the first metal line group is to be formed, use of the first patterning layer 70 so configured facilitates subsequent formation of two line segments that are aligned in the Y-axis direction in each of the first and second mandrels 42, as opposed to cutting each of the first and second mandrels 42 into two sections, and this makes adjacent columns of the line segments in the first line pattern (e.g., the column of the metal lines A₁₋₁, A₁₋₂ and the column of the metal lines A₂₋₁, A₂₋₂ in FIG. 1) able to have different line-end distances (e.g., the line-end distances d_{A1}, d_{A2} in FIG. 1) using a single lithography process instead of using multiple lithography processes which may result in a significant cost and high fabrication complexity. The first patterning layer 70 may be of either a single-layer structure or a multi-layer structure, and include, for example, an organic material (e.g., a photoresist material), SiCN, SiO₂, SiNₓ, AlOₓN_{y}, metal oxide (MOₓ, where M can be, for example, Ru, W, Ta, Ti, Al, Co, or other suitable metal elements), other suitable materials, or any combination thereof. The first patterning layer 70 may be treated with exposure and developing processes to form the openings therein.

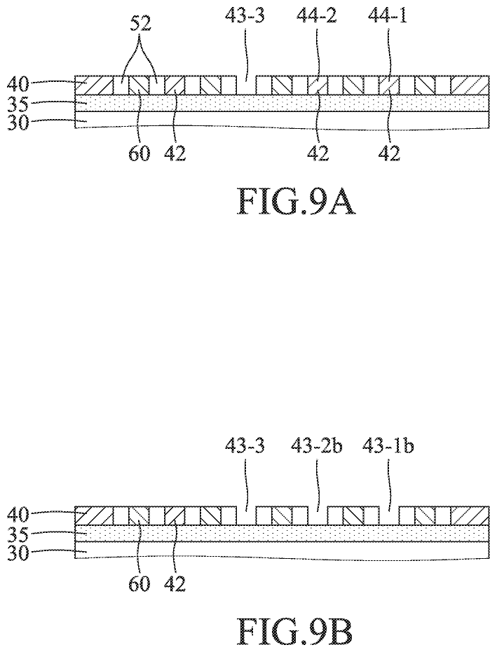

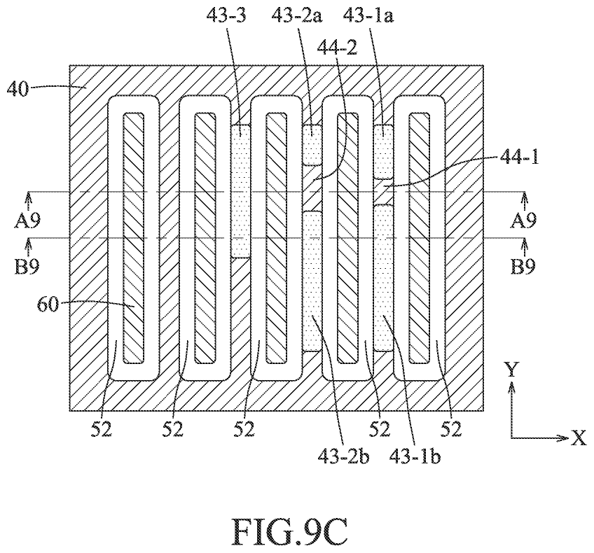

Referring to FIGS. 2, 9A, 9B and 9C, the exposed portions of the mandrels 42 of the mandrel layer 40 are etched with the first patterning layer 70 serving as a mask to form the first line pattern in the mandrel layer 40 (step S7). FIG. 9C is a top view of a structure at this stage, FIG. 9A depicts a sectional view taken along line A9-A9 in FIG. 9C, and FIG. 9B depicts a sectional view taken along line B9-B9 in FIG. 9C. The etching of the mandrels 42 may be performed using, for example, wet etching, dry etching, other suitable techniques, or any combination thereof. In the illustrative embodiment, the first line pattern is formed to have first to fifth line segments that respectively correspond to multiple openings 43-1a, 43-1b, 43-2a, 43-2b and 43-3 that expose the second thin film layer 35 and that are formed in the mandrel layer 40 by etching the exposed portions of the mandrels 42. In correspondence to the first and second openings of the first patterning layer 70, the first line segment and the second line segment that respectively correspond to the openings 43-1a, 43-1b extend in the Y-axis direction, and are aligned with and spaced apart from each other in the Y-axis direction by a first line-end distance ranging from about 2 nm to about 50 nm. In correspondence to the third and fourth openings of the first patterning layer 70, the third line segment and the fourth line segment that respectively correspond to the openings 43-2a. 43-2b extend in the Y-axis direction, and are aligned with and spaced apart from each other in the Y-axis direction by a second line-end distance ranging from about 2 nm to about 50 nm. In the first line pattern of the illustrative embodiment, the first and second line segments are adjacent to the third and fourth line segments in the X-axis direction, and the first line-end distance is different from the second line-end distance because the portions 70A and 70B of the first patterning layer 70 are formed to have different lengths in the Y-axis direction. In the illustrative embodiment, each of the line segments of the first line pattern has a respective uniform line width in the X-axis direction, but this disclosure is not limited in this respect.

Following the first patterning process, a second patterning process is performed to pattern the filling features 60 to form a second line pattern. It is noted that, in accordance with some embodiments, the second patterning process is performed prior to the first patterning process, namely, the mandrel layer 40 is patterned after the patterning of the filling features 60, and this disclosure is not limited in this respect. In accordance with some embodiments, the second patterning process may include steps S8 and S9 as illustrated in FIG. 2.

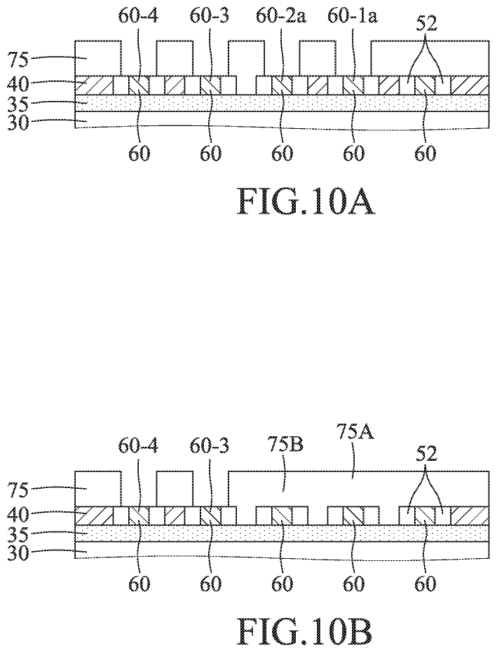

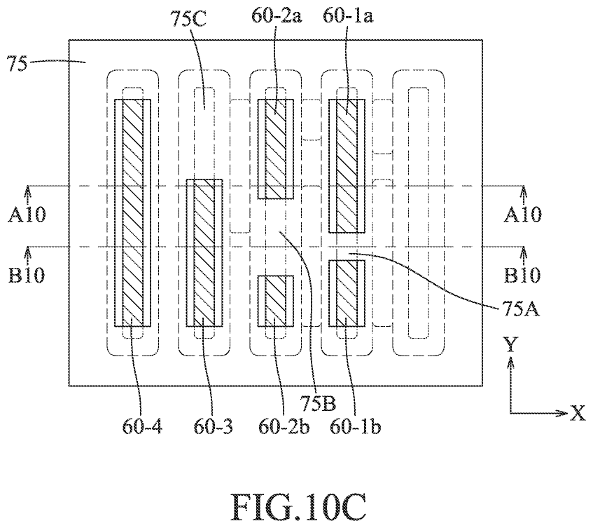

Referring to FIGS. 2, 10A, 10B and 10C, a second patterning layer 75 is formed over the mandrel layer 40, the spacers 52 and the filling features 60 (step S8). FIG. 10C is a top view of a structure at this stage, FIG. 10A depicts a sectional view taken along line A10-A10 in FIG. 10C, and FIG. 10B depicts a sectional view taken along line B10-B10 in FIG. 10C. The second patterning layer 75 covers each of the mandrels 42 (namely, the mandrels 42 are masked by the second patterning layer 75) and is formed with multiple openings that correspond to the second line pattern and that expose a part of the filling features 60 through a lithography process. In the illustrative embodiment, the second patterning layer 75 completely covers the mandrel layer 40, namely, the mandrel layer 40 is completely masked by the second patterning layer 75, but this disclosure is not limited in this respect. In the illustrative embodiment, the second patterning layer 75 is formed with first to sixth openings that respectively expose six portions 60-1a, 60-1b, 60-2a, 60-2b, 60-3 and 60-4 of the filling features 60, which respectively correspond in position to the metal lines B₁₋₁, B₁₋₂, B₂₋₁, B₂₋₂, B₃ and B₄ of the second metal line group in FIG. 1. A portion 75A of the second patterning layer 75 covers and crosses a middle part of one of the filling features 60 (referred to as a first filling feature hereinafter), and separates the first opening and the second opening of the second patterning layer 75 from each other in the Y-axis direction by a distance ranging from about 2 nm to about 50 nm, so as to define the line-end distance d_{B1} in FIG. 1. A portion 75B of the second patterning layer 75 covers and crosses a middle part of another filling feature 60 (referred to as a second filling feature 60 hereinafter) that is adjacent to the first filling feature 60 (i.e., there is no other filling features 60 between the first and second filling features 60), and separates the third opening and the fourth opening of the second patterning layer 75 from each other in the Y-axis direction by a distance ranging from about 2 nm to about 50 nm, so as to define the line-end distance d_{B2} in FIG. 1. A portion 75C of the second patterning layer 75 covers an upper part (upper from the perspective of FIG. 10C) of yet another filling feature 60 whereas portion of the second patterning layer 75 that correspond in position to upper parts of the first and second filling features 60 are formed with the first and third openings, respectively. In the illustrative embodiment, the portions 75A and 75B that respectively correspond to the adjacent first and second filling features 60 overlap each other when viewed in the X-axis direction, and have different lengths in the Y-axis direction. In the illustrative embodiment, since the openings of the second patterning layer 75 are formed to correspond in position to where the metal lines of the second metal line group are to be formed instead of where no metal line of the second metal line group is to be formed, use of the second patterning layer 75 so configured facilitates subsequent formation of two line segments that are aligned in the Y-axis direction in each of the first and second filling features 60, as opposed to cutting each of the first and second filling features 60 into two sections, and this makes adjacent columns of the line segments in the second line pattern (e.g., the column of the metal lines B₁₋₁, B₁₋₂ and the column of the metal lines B₂₋₁, B₂₋₂ in FIG. 1) able to have different line-end distances (e.g., the line-end distances d_{B1}, d_{B2} in FIG. 1) using a single lithography process instead of using multiple lithography processes which may result in a significant cost and high fabrication complexity. The second patterning layer 75 may be of either a single-layer structure or a multi-layer structure, and include, for example, an organic material (e.g., a photoresist material), SiCN, SiO₂, SiNₓ, AlOₓN_{y}, metal oxide (MOₓ, where M can be, for example, Ru, W, Ta, Ti, Al, Co, or other suitable metal elements), other suitable materials, or any combination thereof. The second patterning layer 75 may be treated with exposure and developing processes to form the openings therein.

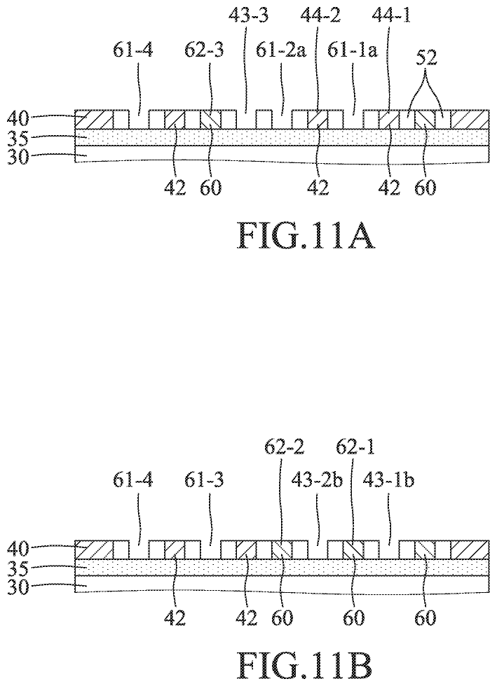

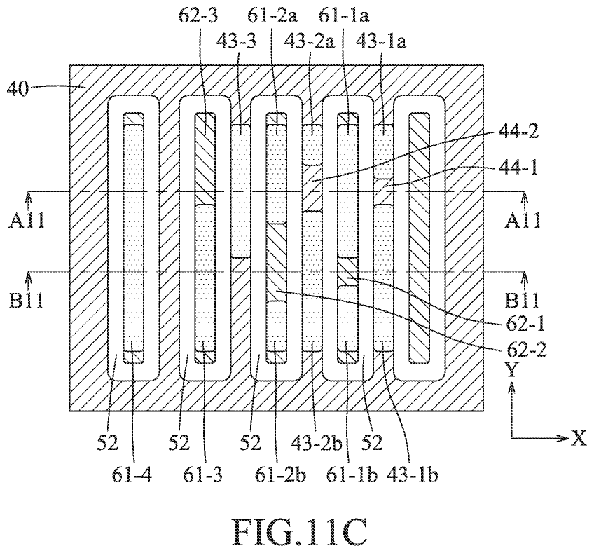

Referring to FIGS. 2, 11A, 11B and 11C, the exposed portions of the filling features 60 are etched with the second patterning layer 75 serving as a mask to form the second line pattern in the filling features 60 (step S9). FIG. 11C is a top view of a structure at this stage, FIG. 11A depicts a sectional view taken along line A11-A11 in FIG. 11C, and FIG. 11B depicts a sectional view taken along line B11-B11 in FIG. 11C. The etching of the filling features 60 may be performed using, for example, wet etching, dry etching, other suitable techniques, or any combination thereof. In the illustrative embodiment, the second line pattern is formed to have first to sixth line segments that respectively correspond to multiple openings 61-1a, 61-1b, 61-2a, 61-2b, 61-3 and 61-4 that expose the second thin film layer 35 and that are formed in the filling features 60 by etching the exposed portions of the filling features 60. In correspondence to the first and second openings of the second patterning layer 75, the first line segment and the second line segment of the second line pattern that respectively correspond to the openings 61-1a, 61-1b extend in the Y-axis direction, and are aligned with and spaced apart from each other in the Y-axis direction by a third line-end distance ranging from about 2 nm to about 50 nm. In correspondence to the third and fourth openings of the second patterning layer 75, the third line segment and the fourth line segment of the second line pattern that respectively correspond to the openings 61-2a, 61-2b extend in the Y-axis direction, and are aligned with and spaced apart from each other in the Y-axis direction by a fourth line-end distance ranging from about 2 nm to about 50 nm. In the second line pattern of the illustrative embodiment, the first and second line segments are adjacent to the third and fourth line segments in the X-axis direction, and the third line-end distance is different from the fourth line-end distance because the portions 75A and 75B of the second patterning layer 75 are formed to have different lengths in the Y-axis direction. In the illustrative embodiment, each of the line segments of the second line pattern has a respective uniform line width in the X-axis direction as defined by the spacers 52, but this disclosure is not limited in this respect.

In some conventional double patterning techniques, a mandrel is formed only when a line segment is to be formed at a position corresponding to the mandrel. Therefore, when one such conventional double patterning technique is used to form the metal line B₄ in FIG. 1, which does not have adjacent thereto a metal line belonging to the first metal line group, no mandrels will be formed at a position between the metal lines B₃ and B₄, and thus no spacers can be formed at the position between the metal lines B₃ and B₄ to define the width of the metal line B₄. As a result, an additional lithography-etching (litho-etch) process may be required to form a pattern of a line segment that corresponds to the metal line B₄, resulting in an additional etching bias that may make a width of the line segment hard to control, and the line segment may thus be wider than expected. In order to solve such a problem, some conventional double patterning techniques may use mandrels to form dummy metal lines, which do not have actual functions in circuits, for controlling the line width of the metal lines defined by spacers. However, the dummy metal lines may create greater resistance-capacitance (RC) delays in the circuits. In the illustrative embodiment, since each of the filling features 60 is confined by a corresponding spacer 52, the line width of each line segment of the second line pattern can be well-controlled during the etching of the filling features 60, regardless of whether or not the line segment has adjacent thereto another line segment that belongs to the first line pattern.

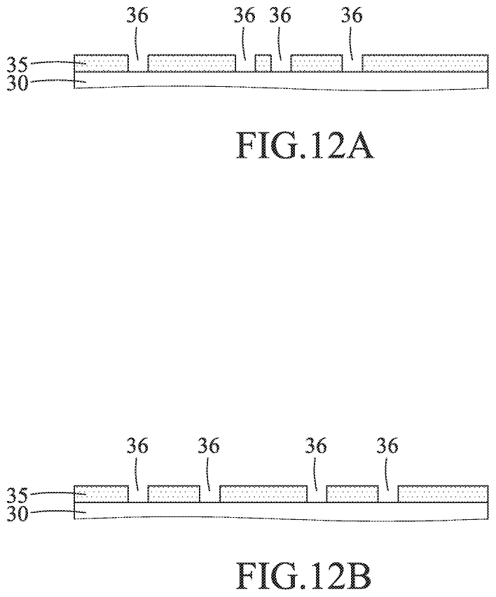

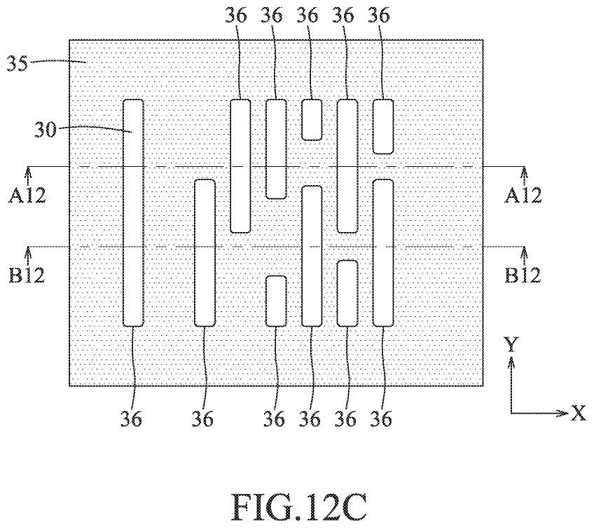

Referring to FIGS. 2, 12A, 12B and 12C, the second thin film layer 35, which is a hard mask layer, is etched (step S10) with the mandrel layer 40, the spacers 52 and the filling features 60 collectively serving as a mask, so as to form a plurality of openings 36 in the second thin film layer 35 with the openings 36 being arranged in a pattern that is a combination of the first line pattern and the second line pattern and exposing the first thin film layer 30. FIG. 12C is a top view of a structure at this stage, FIG. 12A depicts a sectional view taken along line A12-A12 in FIG. 12C, and FIG. 12B depicts a sectional view taken along line B12-B12 in FIG. 12C. The etching of the second thin film layer 35 may be performed using, for example, wet etching, dry etching, other suitable techniques, or any combination thereof. In step S10, the first and second line patterns are transferred to the second thin film layer 35. The mandrel layer 40, the spacers 52 and the filling features 60 may be removed during or after the etching of the second thin film layer 35, and this disclosure is not limited in this respect. In accordance with some embodiments, the mandrel layer 40, the spacers 52 and the filling features 60 may be maintained after the etching of the second thin film layer 35.

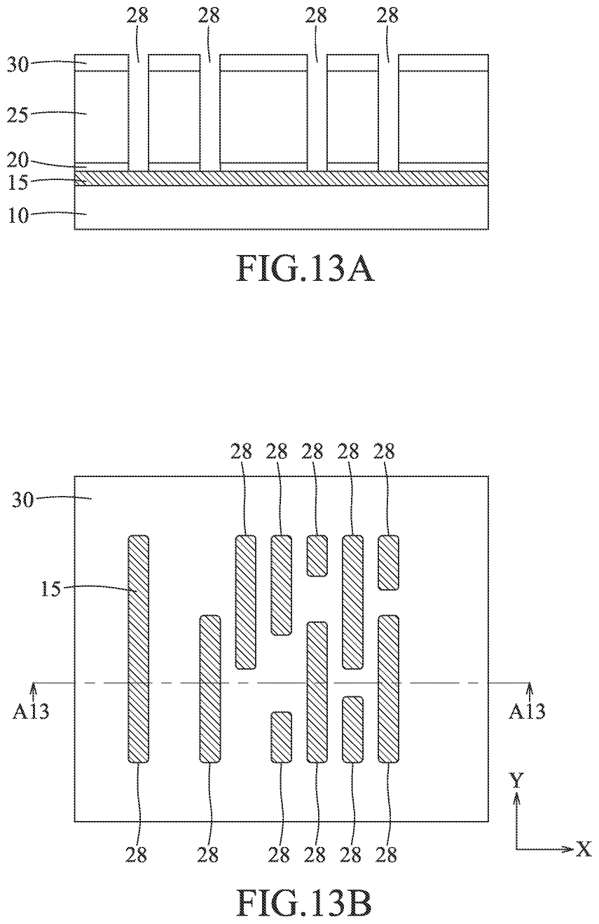

Referring to FIGS. 2, 13A and 13B, the first thin film layer 30, the dielectric layer 25 and the etch stop layer 20 are etched (step S11) with the second thin film layer 35 serving as a mask, so as to form a plurality of openings 28 in the first thin film layer 30, the dielectric layer 25 and the etch stop layer 20 with the openings 28 being arranged in a pattern that is a combination of the first line pattern and the second line pattern and exposing the conductor layer 15. FIG. 13B is a top view of a structure at this stage, and FIG. 13A depicts a sectional view taken along line A13-A13 in FIG. 13B. In step S11, the first and second line patterns are transferred to the first thin film layer 30, the dielectric layer 25 and the etch stop layer 20. The second thin film layer 35 may be removed during or after the etching of the first thin film layer 30, the dielectric layer 25 and the etch stop layer 20, and this disclosure is not limited in this respect. In accordance with some embodiments, the second thin film layer 35 may be maintained after the etching of the first thin film layer 30.

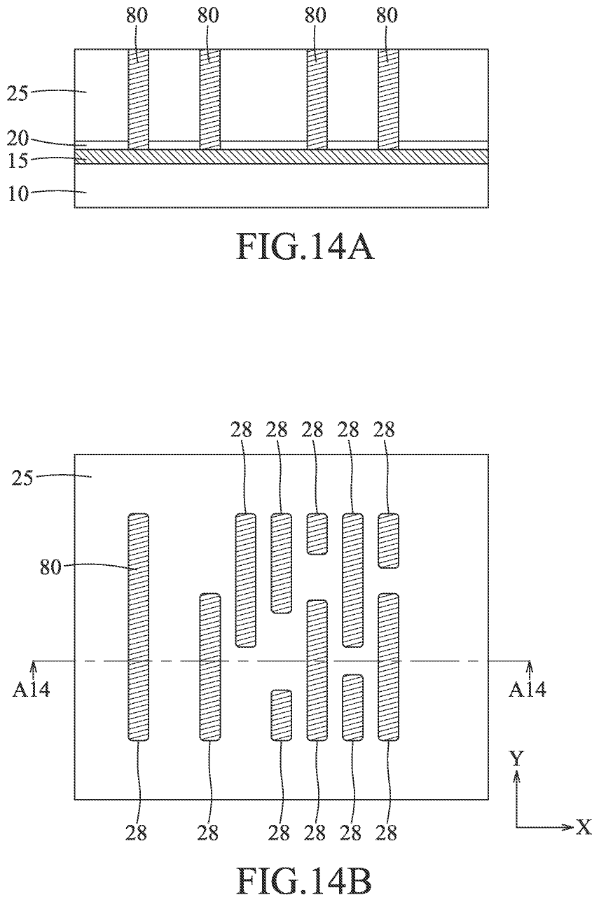

Referring to FIGS. 2, 14A and 14B, a metallization process is performed to deposit a metal layer onto the first thin film layer 30 thus patterned and in the openings 28, followed by a planarization process to form a metal line pattern that combines the first line pattern and the second line pattern (step S12). FIG. 14B is a top view of a structure at this stage, and FIG. 14A depicts a sectional view taken along line A14-A14 in FIG. 14B. The metal line pattern has a plurality of metal lines 80 that are arranged in a pattern that is a combination of the first line pattern and the second line pattern. In the illustrative embodiment, the metal lines 80 shown in FIG. 14B are the metal lines A₁₋₁, A₁₋₂, A₂₋₁, A₂₋₂ and A₃ of the first metal line group and the metal lines B₁₋₁, B₁₋₂, B₂₋₁, B₂₋₂, B₃ and B₄ of the second metal line group in FIG. 1. The metal layer may be deposited using, for example, ALD, PVD, CVD, electrochemical plating (ECP), other suitable techniques, or any combination thereof.

Referring to FIG. 1 again, in the illustrative embodiment, the metal lines B₃, B₄ are adjacent to each other in the second line pattern, and none of the metal lines in the first line pattern is disposed between the metal lines B₃, B₄ (i.e., each of the metal lines formed in the first line pattern is disposed outside of a space between the metal lines B₃, B₄). However, because the embodiment uses the filling features 60 that are confined by the spacers 52 to form the patterns corresponding to the metal lines B₃, B₄, the line widths of the metal lines B₃, B₄ can be well-controlled as designed without the need to form additional dummy metal lines between the metal lines B₃, B₄, thereby reducing the overall capacitance in the circuit. The use of the filling features 60 that are confined by the spacers 52 further makes the metal line B₃ have a uniform width in the X-axis direction as designed even if only a part, and not the whole, of the metal line B₃, which is longer than the adjacent metal line A₃, has the metal line A₃ adjacent thereto when viewed in the X-axis direction, without requiring formation of dummy metal lines adjacent to the part of the metal line B₃ not having the metal line A₃ adjacent thereto when viewed in the X-axis direction in order to keep the width of the metal line B₃ substantially the same from end to end. Without the need of dummy metal lines, routing congestion may be relaxed and layout designs may be more flexible.

In accordance with some embodiments, a method for metal patterning is provided to include multiple steps. In one step, a plurality of mandrel recesses are formed in a mandrel layer over a semiconductor substrate. In one step, a plurality of spacers are formed respectively in the mandrel recesses. Each of the spacers is connected to a sidewall of the corresponding one of the mandrel recesses and has a spacer recess formed therein. In one step, a plurality of filling features are formed respectively in the spacer recesses. In one step, a first patterning process is performed to pattern the mandrel layer to form a first line pattern. In one step, a second patterning process is performed to pattern the filling features to form a second line pattern. In the semiconductor substrate, metal lines are formed to be arranged in a pattern that is a combination of the first line pattern and the second line pattern.

In accordance with some embodiments, in the step of forming the plurality of the filling features, a reverse material layer is deposited on the mandrel layer and the spacers and in the spacer recesses, and a planarization process is performed on the reverse material layer to reveal the mandrel layer and the spacers, so as to form the filling features that are formed by a portion of the reverse material layer filled in the spacer recesses.

In accordance with some embodiments, the reverse material layer includes one of a silicon-containing oxide, a silicon-containing nitride, a metal oxide, a metal nitride, a metal carbide, and a combination thereof.

In accordance with some embodiments, in the first patterning process, a first patterning layer is formed over the mandrel layer, the spacers and the filling features, where the first patterning layer covers each of the filling features and is formed with multiple openings that correspond to the first line pattern and that expose parts of the mandrel layer; and the parts of the mandrel layer are etched with the first patterning layer serving as a mask to form the first line pattern in the mandrel layer.

In accordance with some embodiments, the first line pattern includes a first line segment and a second line segment that extend in a first direction, that are aligned in the first direction, and that are spaced apart from each other in the first direction by a first line-end distance ranging from 2 nm to 50 nm. The first line pattern includes a third line segment and a fourth line segment that extend in the first direction, that are aligned in the first direction, and that are spaced apart from each other in the first direction by a second line-end distance ranging from 2 nm to 50 nm. In the first line pattern, the third line segment and the fourth line segment are adjacent to the first line segment and the second line segment in a second direction perpendicular to the first direction. The first line-end distance is different from the second line-end distance.

In accordance with some embodiments, in the second patterning process, a second patterning layer is formed over the mandrel layer, the spacers and the filling features, where the second patterning layer covers the mandrel layer and is formed with multiple openings that correspond to the second line pattern and that expose parts of the filling features; and the parts of the filling features are etched with the second patterning layer serving as a mask to form the second line pattern in the filling features.

In accordance with some embodiments, the second line pattern includes a first line segment and a second line segment that extend in a first direction, that are aligned in the first direction, and that are spaced apart from each other in the first direction by a first line-end distance ranging from 2 nm to 50 nm. The second line pattern includes a third line segment and a fourth line segment that extend in the first direction, that are aligned in the first direction, and that are spaced apart from each other in the first direction by a second line-end distance ranging from 2 nm to 50 nm. In the second line pattern, the third line segment and the fourth line segment are adjacent to the first line segment and the second line segment in a second direction perpendicular to the first direction. The first line-end distance is different from the second line-end distance.

In accordance with some embodiments, the metal lines correspond in position to the openings formed in the first patterning layer and the second patterning layer.

In accordance with some embodiments, one of the filling features extends in a first direction, and has a uniform width in a second direction perpendicular to the first direction. The first line pattern includes a first line segment that extends in the first direction. The second line pattern includes a second line segment that extends in the first direction, that corresponds in position to said one of the filling features. The second line segment is adjacent to the first line segment in the second direction, and is spaced apart from the first line segment in the second direction by a distance ranging from 5 nm to 50 nm. A length of the first line segment in the first direction is shorter than a length of the second line segment in the first direction, and the first line segment overlaps a portion of the second line segment when viewed in the second direction. The second line segment has a uniform width in the second direction.

In accordance with some embodiments, the metal lines extend in a first direction, and are arranged in a second direction perpendicular to the first direction. The metal lines include a plurality of first metal lines that are arranged in the first line pattern, and a plurality of second metal lines that are arranged in the second line pattern. Two of the second metal lines are adjacent to each other in the second line pattern, and each of the first metal lines is disposed outside of a space between the two of the second metal lines.

In accordance with some embodiments, the semiconductor substrate includes a dielectric layer, and a masking layer disposed on the dielectric layer, the mandrel layer being formed over the masking layer. In the first patterning process, the mandrel layer is patterned to include a plurality of first openings that expose the masking layer. In the second patterning process, the filling features are patterned to include a plurality of second openings that expose the masking layer. In the step of forming the metal lines, the masking layer is etched with the mandrel layer, the spacers and the filling features thus patterned serving as a mask to form the first line pattern and the second line pattern in the masking layer; the dielectric layer is etched with the masking layer thus etched serving as a mask to form the first line pattern and the second line pattern in the dielectric layer; and a metal material is deposited onto the dielectric layer thus etched to form the metal lines.

In accordance with some embodiments, the first patterning process and the second patterning process are performed separately.

In accordance with some embodiments, a method for metal patterning is provided to include multiple steps. In one step, a semiconductor substrate is provided to include a masking layer on top. In one step, a mandrel layer is formed over the masking layer. In one step, the mandrel layer is patterned to form in the mandrel layer a mandrel recess that exposes the masking layer. In one step, a spacer layer is formed conformally onto the mandrel layer and in the mandrel recess. In one step, the spacer layer is etched to reveal a top surface of the mandrel layer and to form a spacer recess in the spacer layer and in the mandrel recess, wherein the spacer recess exposes the masking layer. In one step, a filling feature is formed to fill the spacer recess. In one step, the mandrel layer is patterned to form a first line pattern in the mandrel layer. In one step, the filling feature is patterned to form a second line pattern in the filling feature. In one step, the masking layer is patterned to have the first line pattern and the second line pattern with the mandrel layer and the filling feature thus patterned serving as a mask. In one step, a metal layer is deposited on the masking layer thus patterned to form a metal line pattern that combines the first line pattern and the second line pattern.

In accordance with some embodiments, in the step of forming the filling feature, a reverse material layer is deposited on the mandrel layer and the spacer layer and in the spacer recess; and a planarization process is performed to reveal the mandrel layer and the spacer layer, so as to form the filling feature that is a part of the reverse material layer filled in the spacer recess.

In accordance with some embodiments, the reverse material layer includes one of a silicon-containing oxide, a silicon-containing nitride, a metal oxide, a metal nitride, a metal carbide, and a combination thereof.

In accordance with some embodiments, the filling feature is masked in the step of patterning the mandrel layer.

In accordance with some embodiments, a method for metal patterning is provided to include multiple steps. In one step, a mandrel layer is formed onto a semiconductor substrate. The mandrel layer is formed with a first mandrel opening and a second mandrel opening that extend in a first direction, that are adjacent to each other in a second direction perpendicular to the first direction, and that expose the semiconductor substrate. In one step, a first spacer feature is formed onto a sidewall of the first mandrel opening, and a second spacer feature onto a sidewall of the second mandrel opening. The first spacer feature is formed with a first spacer opening that extends in the first direction and that exposes the semiconductor substrate, and the second spacer feature is formed with a second spacer opening that extends in the first direction and that exposes the semiconductor substrate. In one step, the first spacer opening and the second spacer opening are filled with a reverse material to form a first filling feature and a second filling feature respectively in the first spacer opening and the second spacer opening. In one step, the mandrel layer is patterned at a position between the first mandrel opening and the second mandrel opening to form a first line pattern. In one step, the first filling feature and the second filling feature are patterned to form a second line pattern. In one step, in the semiconductor substrate, metal lines are formed to be arranged in the first line pattern and the second line pattern.

In accordance with some embodiments, the first spacer opening has a uniform width in the second direction. The metal lines include a first metal line that corresponds in position to a portion of the mandrel layer disposed at the position between the first mandrel opening and the second mandrel opening, and a second metal line that corresponds in position to the first filling feature. The first metal line is shorter than the second metal line, and the second metal line has a uniform width in the second direction.

In accordance with some embodiments, the second line pattern includes a first line segment and a second line segment that correspond in position to the first filling feature, and a third line segment and a fourth line segment that correspond in position to the second filling feature. The first line segment and the second line segment are aligned with and spaced apart from each other in the first direction, and the third line segment and the fourth line segment are aligned with and spaced apart from each other in the first direction. A line-end distance between the first line segment and the second line segment is different from a line-end distance between the third line segment and the fourth line segment.

In accordance with some embodiments, the first filling feature and the second filling feature are masked in the step of patterning the mandrel layer. In the step of patterning the first filling feature and the second filling feature, a portion of the mandrel layer that is disposed at the position between the first mandrel opening and the second mandrel opening is masked.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for metal patterning, comprising steps of:
forming a plurality of mandrel recesses in a mandrel layer over a semiconductor substrate;
forming a plurality of spacers respectively in the mandrel recesses, each of the spacers being connected to a sidewall of the corresponding one of the mandrel recesses and having a spacer recess formed therein;
forming a plurality of filling features respectively in the spacer recesses;
performing a first patterning process to pattern the mandrel layer to form a first line pattern;
performing a second patterning process to pattern the filling features to form a second line pattern;
forming, in the semiconductor substrate, metal lines that are arranged in a pattern which is a combination of the first line pattern and the second line pattern.

2. The method according to claim 1, wherein the step of forming the plurality of the filling features includes:
depositing a reverse material layer on the mandrel layer and the spacers and in the spacer recesses; and
performing a planarization process on the reverse material layer to reveal the mandrel layer and the spacers, so as to form the filling features that are formed by a portion of the reverse material layer filled in the spacer recesses.

3. The method according to claim 2, wherein the reverse material layer includes one of a silicon-containing oxide, a silicon-containing nitride, a metal oxide, a metal nitride, a metal carbide, and a combination thereof.

4. The method according to claim 1, wherein the first patterning process includes:
forming a first patterning layer over the mandrel layer, the spacers and the filling features, where the first patterning layer covers each of the filling features and is formed with multiple openings that correspond to the first line pattern and that expose parts of the mandrel layer; and
etching the parts of the mandrel layer with the first patterning layer serving as a mask to form the first line pattern in the mandrel layer.

5. The method according to claim 4, wherein the first line pattern includes a first line segment and a second line segment that extend in a first direction, that are aligned in the first direction, and that are spaced apart from each other in the first direction by a first line-end distance ranging from 2 nm to 50 nm;
wherein the first line pattern includes a third line segment and a fourth line segment that extend in the first direction, that are aligned in the first direction, and that are spaced apart from each other in the first direction by a second line-end distance ranging from 2 nm to 50 nm;
wherein, in the first line pattern, the third line segment and the fourth line segment are adjacent to the first line segment and the second line segment in a second direction perpendicular to the first direction; and
wherein the first line-end distance is different from the second line-end distance.

6. The method according to claim 4, wherein the second patterning process includes:
forming a second patterning layer over the mandrel layer, the spacers and the filling features, where the second patterning layer covers the mandrel layer and is formed with multiple openings that correspond to the second line pattern and that expose parts of the filling features; and
etching the parts of the filling features with the second patterning layer serving as a mask to form the second line pattern in the filling features.

7. The method according to claim 6, wherein the second line pattern includes a first line segment and a second line segment that extend in a first direction, that are aligned in the first direction, and that are spaced apart from each other in the first direction by a first line-end distance ranging from 2 nm to 50 nm;
wherein the second line pattern includes a third line segment and a fourth line segment that extend in the first direction, that are aligned in the first direction, and that are spaced apart from each other in the first direction by a second line-end distance ranging from 2 nm to 50 nm;
wherein, in the second line pattern, the third line segment and the fourth line segment are adjacent to the first line segment and the second line segment in a second direction perpendicular to the first direction; and
wherein the first line-end distance is different from the second line-end distance.

8. The method according to claim 6, wherein the metal lines correspond in position to the openings formed in the first patterning layer and the second patterning layer.

9. The method according to claim 1, wherein one of the filling features extends in a first direction, and has a uniform width in a second direction perpendicular to the first direction;
wherein the first line pattern includes a first line segment that extends in the first direction;
wherein the second line pattern includes a second line segment that extends in the first direction, that corresponds in position to said one of the filling features;
wherein the second line segment is adjacent to the first line segment in the second direction, and is spaced apart from the first line segment in the second direction by a distance ranging from 5 nm to 50 nm;
wherein a length of the first line segment in the first direction is shorter than a length of the second line segment in the first direction, and the first line segment overlaps a portion of the second line segment when viewed in the second direction; and
wherein the second line segment has a uniform width in the second direction.

10. The method according to claim 1, wherein the metal lines extend in a first direction, and are arranged in a second direction perpendicular to the first direction;
wherein the metal lines include a plurality of first metal lines that are arranged in the first line pattern, and a plurality of second metal lines that are arranged in the second line pattern; and
wherein two of the second metal lines are adjacent to each other in the second line pattern, and each of the first metal lines is disposed outside of a space between the two of the second metal lines.

11. The method according to claim 1, wherein the semiconductor substrate includes a dielectric layer, and a masking layer disposed on the dielectric layer, the mandrel layer being formed over the masking layer;
wherein, in the first patterning process, the mandrel layer is patterned to include a plurality of first openings that expose the masking layer;
wherein, in the second patterning process, the filling features are patterned to include a plurality of second openings that expose the masking layer; and
wherein the step of forming the metal lines includes:
etching the masking layer with the mandrel layer, the spacers and the filling features thus patterned serving as a mask to form the first line pattern and the second line pattern in the masking layer;
etching the dielectric layer with the masking layer thus etched serving as a mask to form the first line pattern and the second line pattern in the dielectric layer; and
depositing a metal material onto the dielectric layer thus etched to form the metal lines.

12. The method according to claim 1, wherein the first patterning process and the second patterning process are performed separately.

13. A method for metal patterning, comprising steps of:
providing a semiconductor substrate that includes a masking layer on top;
forming a mandrel layer over the masking layer;
patterning the mandrel layer to form in the mandrel layer a mandrel recess that exposes the masking layer;
forming a spacer layer conformally onto the mandrel layer and in the mandrel recess;
etching the spacer layer to reveal a top surface of the mandrel layer and to form a spacer recess in the spacer layer and in the mandrel recess, wherein the spacer recess exposes the masking layer;
forming a filling feature that fills the spacer recess;
patterning the mandrel layer to form a first line pattern in the mandrel layer;
patterning the filling feature to form a second line pattern in the filling feature;
patterning the masking layer to have the first line pattern and the second line pattern with the mandrel layer and the filling feature thus patterned serving as a mask; and
depositing a metal layer on the masking layer thus patterned to form a metal line pattern that combines the first line pattern and the second line pattern.

14. The method according to claim 13, wherein the step of forming the filling feature includes:
depositing a reverse material layer on the mandrel layer and the spacer layer and in the spacer recess; and
performing a planarization process to reveal the mandrel layer and the spacer layer, so as to form the filling feature that is a part of the reverse material layer filled in the spacer recess.

15. The method according to claim 14, wherein the reverse material layer includes one of a silicon-containing oxide, a silicon-containing nitride, a metal oxide, a metal nitride, a metal carbide, and a combination thereof.

16. The method according to claim 13, wherein, in the step of patterning the mandrel layer, the filling feature is masked.

17. A method for metal patterning, comprising steps of:
forming a mandrel layer onto a semiconductor substrate, wherein the mandrel layer is formed with a first mandrel opening and a second mandrel opening that extend in a first direction, that are adjacent to each other in a second direction perpendicular to the first direction, and that expose the semiconductor substrate;
forming a first spacer feature onto a sidewall of the first mandrel opening, and a second spacer feature onto a sidewall of the second mandrel opening, wherein the first spacer feature is formed with a first spacer opening that extends in the first direction and that exposes the semiconductor substrate, and the second spacer feature is formed with a second spacer opening that extends in the first direction and that exposes the semiconductor substrate;
filling the first spacer opening and the second spacer opening with a reverse material to form a first filling feature and a second filling feature respectively in the first spacer opening and the second spacer opening;
patterning the mandrel layer at a position between the first mandrel opening and the second mandrel opening to form a first line pattern;
patterning the first filling feature and the second filling feature to form a second line pattern; and
forming, in the semiconductor substrate, metal lines that are arranged in the first line pattern and the second line pattern.

18. The method according to claim 17, wherein the first spacer opening has a uniform width in the second direction;
wherein the metal lines include a first metal line that corresponds in position to a portion of the mandrel layer disposed at the position between the first mandrel opening and the second mandrel opening, and a second metal line that corresponds in position to the first filling feature; and
wherein the first metal line is shorter than the second metal line, and the second metal line has a uniform width in the second direction.

19. The method according to claim 17, wherein the second line pattern includes a first line segment and a second line segment that correspond in position to the first filling feature, and a third line segment and a fourth line segment that correspond in position to the second filling feature;
wherein the first line segment and the second line segment are aligned with and spaced apart from each other in the first direction, and the third line segment and the fourth line segment are aligned with and spaced apart from each other in the first direction; and
wherein a line-end distance between the first line segment and the second line segment is different from a line-end distance between the third line segment and the fourth line segment.

20. The method according to claim 17, wherein, in the step of patterning the mandrel layer, the first filling feature and the second filling feature are masked; and
wherein, in the step of patterning the first filling feature and the second filling feature, a portion of the mandrel layer that is disposed at the position between the first mandrel opening and the second mandrel opening is masked.
